(19) United States
(12) Patent Application Publication
(10) Pub. No.: US 2025/0294724 A1
(43) Pub. Date: Sep. 18, 2025

(54) SEMICONDUCTOR DEVICE AND METHOD OF FABRICATING THE SAME

(71) Applicant: Fujian Jinhua Integrated Circuit Co., Ltd., Quanzhou City (CN)

(72) Inventors: Li-Wei Feng, Quanzhou City (CN); Janbo Zhang, Quanzhou City (CN); YIRONG XU, Quanzhou City (CN)

(73) Assignee: Fujian Jinhua Integrated Circuit Co., Ltd., Quanzhou City (CN)

(21) Appl. No.: 18/764,092

(22) Filed: Jul. 3, 2024

(30) Foreign Application Priority Data
Mar. 18, 2024 (CN) 202410308718.0

(51) Int. Cl. H10B 12/00; H01L 21/762

(52) U.S. Cl. CPC H10B 12/482; H10B 12/0335; H10B 12/09; H10B 12/315; H01L 21/76224

(57) ABSTRACT

The present disclosure provided a semiconductor device and a method of fabricating the same, includes a substrate, bit lines, a spacer and an isolating structure. At least one bit line includes a first bit line and a second bit line, and the second bit line is disposed adjacent to a short-end of the first bit line. The spacer is disposed between the first bit line and the second bit line, and in physical contact with the first bit line and the second bit line respectively. The isolating structure is disposed on the substrate, simultaneously covering a portion of the first bit line, a portion of the second bit line and a portion of the spacer.

### BACKGROUND OF THE INVENTION

### 1. Field of the Invention

The present invention generally relates to a semiconductor device and a method of fabricating the same, and more particularly, to a semiconductor device including bit lines and a spacer structure, and a method of fabricating the same.

### 2. Description of the Prior Art

With the trend of miniaturization of various electronic products, the design of semiconductor devices must also meet the requirements of high integration and high density. Under the current mainstream of development trend, dynamic random access memories (DRAMs) having recessed gate structures have gradually replaced the DRAMs having only planar gate structures due to longer carrier channel length for the same semiconductor substrate so as to reduce current leakage of capacitor structures. In general, a DRAM cell with a recessed gate structure includes a transistor component and a charge storage device to receive voltage signals from bit lines and word lines. However, due to the limitations of current processing technologies, there are still many defects in currently available DRAM cells with recessed gate structures, which need to be further improved to effectively improve the performance and reliability of related memory devices.

### SUMMARY OF THE INVENTION

An object of the present disclosure is to provide a semiconductor device and a fabricating method thereof, where isolating structures having various extending lengths and/or penetrating through components with various materials are arranged within the periphery region and the cell region of the semiconductor device, for achieving various isolation effects. In this way, the arrangements of the isolating structures enable to improve the structural reliability, as well as the device performance, of the semiconductor device thereby.

In order to achieve the above object, an embodiment of the present disclosure provides a semiconductor device including a substrate, bit lines, a spacer and an isolating structure. The bit lines are disposed on the substrate, extending in a first direction and being arranged in a second direction perpendicular to the first direction. At least one of the bit lines includes a first bit line within the cell region and a second bit line within the peripheral region, and the second bit line is disposed adjacent to a short-end of the first bit line extending in the second direction. The spacer is disposed between the first bit line and the second bit line, and in physical contact with the first bit line and the second bit line respectively. The isolating structure is disposed on the substrate, wherein the isolating structure simultaneously covers a portion of the first bit line, a portion of the second bit line and a portion of the spacer.

In order to achieve the above object, an embodiment of the present disclosure provides a method of forming a semiconductor device including the following steps. A substrate is provided, and a plurality of bit lines is formed on the substrate, extending in a first direction and being arranged in a second direction perpendicular to the first direction. At least one of the bit lines includes a first bit line and a second bit line, and the second bit line is disposed adjacent to a short-end of the first bit line extending in the second direction. A spacer is formed between the first bit line and the second bit line, physical contacting the first bit line and the second bit line respectively. An isolating structure is formed on the substrate, wherein the isolating structure simultaneously covers a portion of the first bit line, a portion of the second bit line and a portion of the spacer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 to FIG. 5 are schematic diagrams illustrating a semiconductor device according to a first embodiment of the present disclosure, wherein:

FIG. 1 illustrates a top view of the semiconductor device;

FIG. 2 illustrates a cross-sectional view taken along a cross line A-A′ in FIG. 1;

FIG. 3 illustrates a cross-sectional view taken along a cross line B-B′ in FIG. 1;

FIG. 4 illustrates a cross-sectional view taken along a cross line C-C′ in FIG. 1; and

FIG. 5 illustrates a cross-sectional view taken along a cross line D-D′ in FIG. 1.

FIG. 6 to FIG. 7 are schematic diagrams illustrating a fabricating method of a semiconductor device according to the first embodiment of the present disclosure, wherein:

FIG. 6 illustrates a top view of a semiconductor device after forming a mask layer; and

FIG. 7 illustrates a top view of a semiconductor device after forming an isolating trench.

FIG. 8 to FIG. 9 are schematic diagrams illustrating a fabricating method of a semiconductor device according to a second embodiment of the present disclosure, wherein:

FIG. 8 illustrates a top view of a semiconductor device after forming a mask layer; and

FIG. 9 illustrates a top view of a semiconductor device after forming an isolating structure.

FIG. 10 to FIG. 11 are schematic diagrams illustrating a fabricating method of a semiconductor device according to a third embodiment of the present disclosure, wherein:

FIG. 10 illustrates a top view of a semiconductor device after forming a mask layer; and

FIG. 11 illustrates a top view of a semiconductor device after forming an isolating structure.

### DETAILED DESCRIPTION

For better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

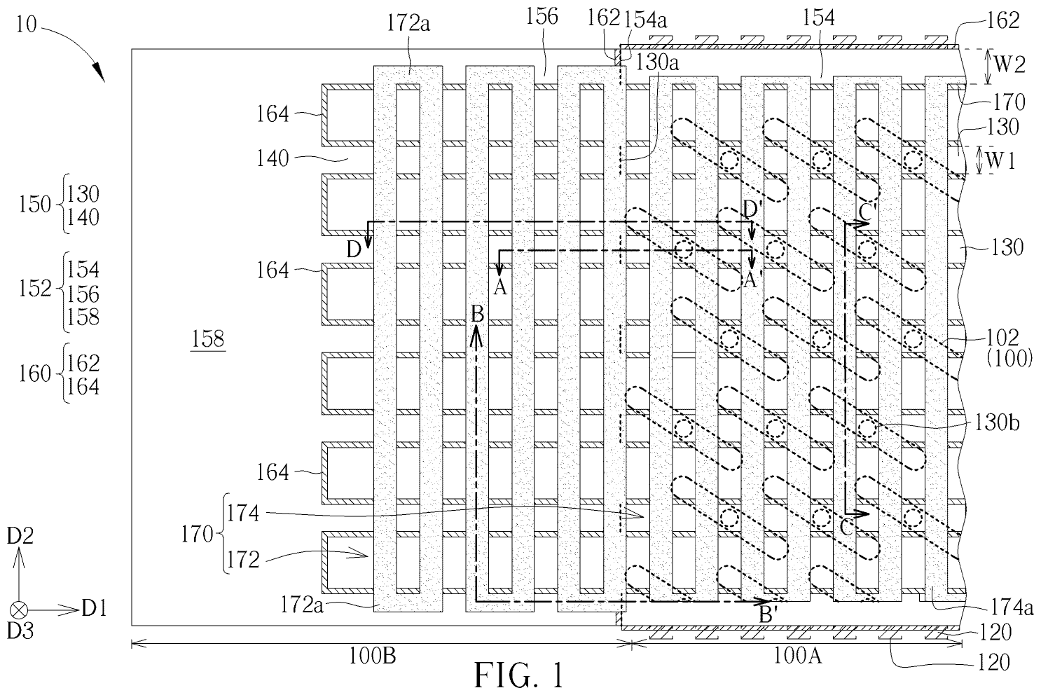

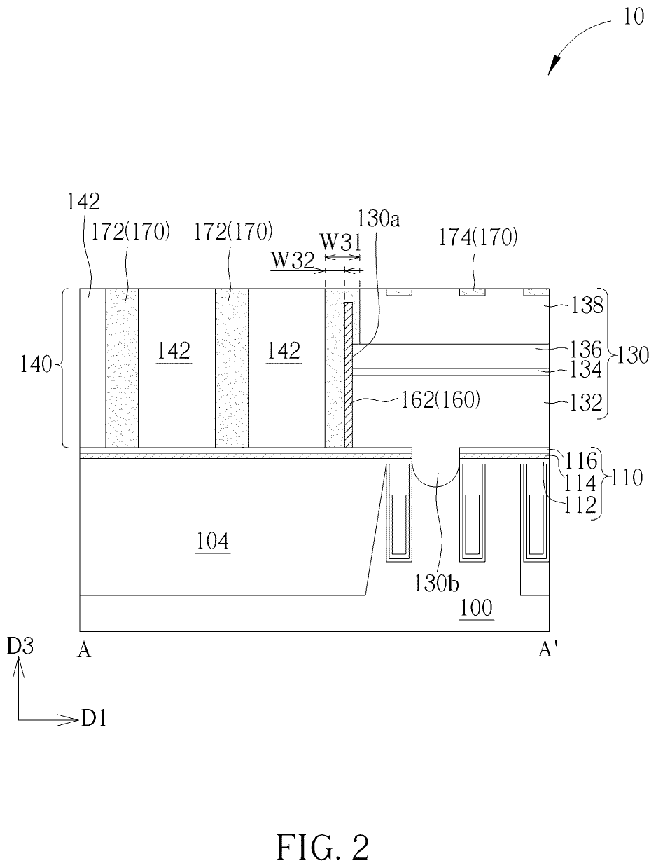

Please refer to FIG. 1 to FIG. 5, which are schematic diagrams illustrating a semiconductor device 10 according to the first embodiment of the present disclosure, with FIG. 1 showing a top view of the semiconductor device 10, and with FIG. 2 to FIG. 5 showing a cross-sectional view in various cross lines of the semiconductor device 10, respectively. The semiconductor device 10 includes a substrate 100, a plurality of bit lines 150, a spacer 162, and a plurality of isolating structures 170. The substrate for example includes a silicon substrate, a silicon-containing substrate (e.g., SiC or SiGe), an epitaxial silicon substrate, a silicon-on-insulator (SOI) substrate, or a substrate formed of any other suitable materials, but not limited thereto. The substrate 100 further includes a cell region 100A with a relative higher elemental integration, and a periphery region 100B with a relative lower elemental integration, with the cell region 100A and the periphery region 100B being adjacent to each other, but not limited thereto. Also, the substrate 100 further includes a plurality of shallow trench isolations 104 (for example including silicon oxide) disposed therein, to define a plurality of active areas 102 in the same direction (not shown in the drawings), within the substrate 100.

Please refer to FIG. 1 and FIG. 2, the bit lines are disposed on the substrate 100, and each further includes a first bit line 130 and a second bit line 140 in connection with each other. The first bit line 130 extends in a first direction D1, within the cell region 100A, and the second bit line 140 also extends in the first direction D1, within the peripheral region 100B. A side of the second bit line 140 in the second direction D2 is disposed adjacent to the short-end 130a of the first bit line 130 extending in the second direction D2, so that, the first bit line 130 and the second bit line 140 of each bit line 150 are substantially in a continuous extending structure in the first direction D1. The first bit line 130 and the second bit line 140 of each bit line 150 are arranged in sequence in the second direction D2 being perpendicular to the first direction D1, and the spacer 162 is sandwiched between the short-end 130a of the first bit line 130 and the side of the second bit line 140 in the first direction D1, with the spacer 162 physically contacting the sidewalls of the first bit line 130 and the second bit line 140, respectively. It is noted that the isolating structures 170 are disposed on the substrate 100, extending in the second direction D2, wherein at least one of the isolating structures 172 simultaneously covers a portion of the first bit line 130, a portion of the second bit line 140 and a portion of the spacer 162, as shown in FIG. 1. Accordingly, the isolating structures 172 arranged within the peripheral region 100B of the substrate 100 is allowable to achieve various isolation effects, so as to improve the structural reliability, as well as the device performance, of the semiconductor device 10 thereby.

In one embodiment, at least one isolating structure 172 penetrates through the second bit line 140 of each bit line 150 at the same time, in a third direction D3 being perpendicular to the first direction D1 and the second direction D2, as shown in FIG. 1 and FIG. 2. Precisely speaking, the semiconductor device 10 further includes a plurality of dummy bit lines 152 disposed on the substrate 100, and a bit line spacer 164 disposed on the sidewalls of the bit lines and the dummy bit lines 152. The bit line spacer 164 and the spacer 162 together form a spacer structure 160. The dummy bit lines 152 are disposed at two opposite sides of all of the bit lines 150 in the second direction D2, and which include a relative larger width W2 in the second direction D2, for example being about 1.3 time larger than an average width W1 of the bit lines 150 in the second direction D2, as shown in FIG. 2, but not limited thereto. Each of the dummy bit lines 152 further includes a third bit line 154 and a fourth bit line 156 in the first direction D1, within the cell region 100A and the peripheral region 100B respectively. Also, a side of the fourth bit line 156 within the peripheral region 100B is disposed adjacent to a short-end 154a of the third bit line 154 within the cell region 100A, such that, the third bit line 154 and the fourth bit line 156 of each dummy bit line 152 are substantially in a continuous extending structure in the first direction D1. The spacer 162 is also sandwiched between the short-end 154a of the third bit line 154 and the fourth bit line 156 in the first direction D1, with the spacer 162 physically contacting the sidewalls of the third bit line 154 and the fourth bit line 156 respectively. Also, the spacer 162 is further disposed on a sidewall of the third bit line 154 at a side being away from the first bit line 130. In one embodiment, the bit line spacer 164 and the spacer 162 for example include the same insulating material or different insulating materials like silicon oxide, silicon oxynitride, silicon nitride, silicon carbonitride. In addition, the bit line spacer 164 and the spacer 162 for example include a monolayer structure as shown in FIG. 1 to FIG. 3, or a multilayer structure (not shown in the drawings), but not limited thereto. In another embodiment, the dummy bit lines 152 further includes a connection 158 extending in the second direction D2, within the peripheral region 100B, with the connection 158 physically contacting the fourth bit line 156 of each dummy bit line 152 and the second bit line 140 of each bit line 150. That is, the fourth bit line 156 of each dummy bit line 152 and the second bit line 140 of each bit line 150 are connected with each other through the connection 158, to overall present in a comb-shape structure as shown in FIG. 1, but not limited thereto.

Please further in view of FIG. 1, each isolating structure 170 partially extends in the second direction D2 and partially extends in the first direction D1, with portions extending in the second direction D2 directly contacting short-ends 172a, 174a extending in the first direction D1, to overall present in a circular shape as shown in FIG. 1, but not limited thereto. In one embodiment, isolating structures 172 are disposed within the peripheral region 100B, each simultaneously intersecting the second bit line of each bit line 150 and the fourth bit line 156 of each dummy bit line 152, and isolating structures 174 are disposed within the cell region 100A, with each simultaneously intersecting through the first bit line 130 of each bit line 150 and the third bit line 154 of each dummy bit line 152. That is, the short-ends 172a, 174a of each isolating structure 170 in the first direction D1 are respectively disposed within the fourth bit line 156 or the third bit line 154 of the dummy bit lines 152. The isolating structures 172 within the peripheral region 100B preferably include an extending length larger than that of the isolating structures 174 within the cell region 100A, but not limited thereto. People skilled in the arts should fully realize that, in another embodiment, the isolating structures structures 172 within the peripheral region 100B may optionally include the same extending length as that of the isolating structures 174 within the cell region 100A, or include other structures.

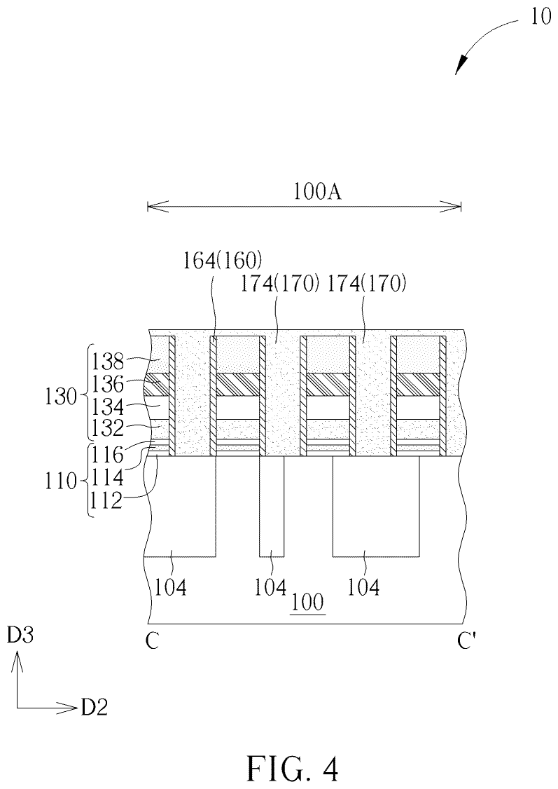

Please refer to FIG. 1 and FIG. 4, the first bit line 130 of each bit line 150 and the third bit line 154 of each dummy bit line 152 further include a semiconductor layer 132 (for example including a semiconductor material like doped polysilicon or doped amorphous silicon), a barrier layer 134 (for example including a barrier material like titanium and/or titanium nitride, tantalum and/or tantalum nitride), a conductive layer 136 (for example including a metal material like tungsten, aluminum or copper), and a capping layer 138 (for example including an insulating material like silicon oxide, silicon nitride or silicon oxynitride) stacked in sequence in the third direction D3. The first bit line 130 and the third bit line 154 are basically disposed on an insulating layer 110 disposed on the substrate 100, with a portion of the semiconductor layer 132 further extending into the substrate 100 to serve as bit line contacts (BLCs) 130b, 154b, so that, the first bit line 130 of each bit line 150 may be electrically connected to the active areas 102 through the bit line contacts 130b which are disposed underneath in a monolithic manner, thereby receiving and transmitting the signals from the substrate 100. In one embodiment, the insulating layer 110 preferably includes a multilayer structure including an oxide layer 112-a nitride layer 114-an oxide layer 116 (oxide-nitride-oxide, ONO) stacked in sequence, but not limited thereto.

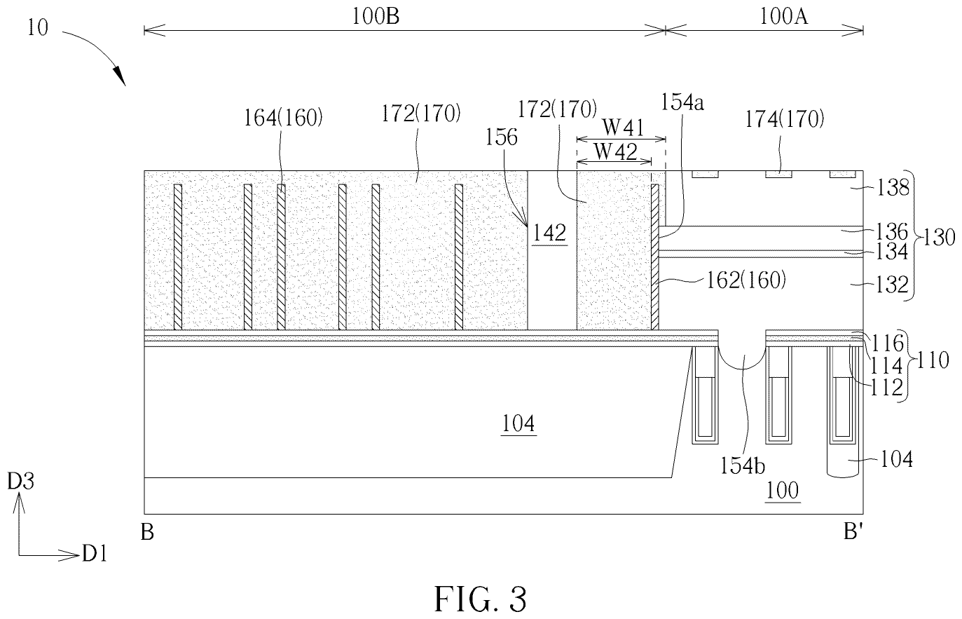

On the other hand, the second bit line 140 of each bit line 150 and the fourth bit line 156 of each dummy bit line 152 further include an insulating layer 142 disposed on the insulating layer 110, with the insulating layer 142 for example includes a material like silicon oxide or silicon oxynitride. Through these arrangements, the portion of the isolating structures 170 in the second direction D2 overlaps a portion of the bit line 150 or a portion of the dummy bit line 152, and the space between the bit line 150 and the dummy bit line 152 adjacent thereof, to have different extending depths in the third direction D3, as shown in FIG. 2 and FIG. 4. Precisely speaking, due to the differences among the materials of the overlapping components, the isolating structures 172 within the peripheral region 100B each penetrates the second bit line 140 (including the insulating layer 142) of each bit line 150 and the fourth bit line 156 (including the insulating layer 142) of each dummy bit line 152 in the third direction D3, to physically contact a top surface of the insulating layer 110 underneath, and the isolating structures 174 with in the cell region 100A are located in the capping layer 138 of the first bit line 130 of each bit line 150 and the capping layer 138 of the third bit line 154 of each dummy bit line 152 in the third direction D3, to physically contact the capping layer 138 of the first bit line 130 and the third bit line 154, as shown in FIGS. 2 and 3. Furthermore, one isolating structure 172 located at the boundary between the peripheral region 100B and the cell region 100A intersects through the first bit line 130 and the second bit line 140 of each bit line 150, and the third bit line 154 and the fourth bit line 156 of each dummy bit line 152 at the same time, in the second direction D2. Also, the isolating structure 172 located at the boundary between the peripheral region 100B and the cell region 100A penetrates through the second bit line 140 (including insulating layer 142) of each bit line 150 and partially penetrates the first bit line 130 of each bit line 150 (only penetrating the capping layer 138 of the first bit line 130) in the third direction D3, to partially contact the top surface of the insulating layer 110 and to partially contact the top surface of the conductive layer 136 of the first bit line 130, and also penetrates through the fourth bit line 156 (including insulating layer 142) of each dummy bit line 152 and partially penetrates the third bit line 154 of each dummy bit line 152 (only penetrating the capping layer 138 of the third bit line 154) in the third direction D3, to partially contact the top surface of the insulating layer 110 and to partially contact the top surface of the conductive layer 136 of the third bit line 154. In other words, the isolating structure 172 located at the boundary between the peripheral region 100B and the cell region 100A directly contacts the sidewalls of the junction between the first bit line 130 and the second bit line 140, as well as the sidewall and the top surface of the spacer 162 disposed between the first bit line 130 and the second bit line 140, as shown in FIG. 2 and FIG. 3. In this way, the upper portion of the isolation structure 172 disposed at the boundary of the peripheral region 100B and the cell region 100A has a relatively large width W31, while the bottom portion has a relatively small width W32 (as shown in FIG. 2). The upper portion of a short-end 172a of the isolation structure 172 disposed at the boundary of the peripheral region 100B and the cell region 100A also has a relatively large width W41 in the dummy bit line 152, while the bottom portion has a relatively small width W42 (as shown in FIG. 3), to overall present in a large top and a small bottom structure.

Further in view of FIG. 1 and FIG. 3, the semiconductor device 10 further includes a plurality of word lines 120 disposed in the substrate, within the cell region 100A, with each word line extending in the second direction D2. Those skilled in the art should fully realize that the extending directions of the active areas 102, the word lines 120, and the bit lines 150 are all different from each other. For example, the extending direction (the second direction D2) of the word lines 120 may be perpendicular to the extending direction (the first direction D1) of the bit lines 150, to simultaneously intersect several active areas 102 and the bit lines 150. The word lines 120 each includes a dielectric layer 122, a gate dielectric layer 124 and a gate layer 126 stacked in sequence, and a capping layer 128 disposed on the gate layer 126, as shown in FIG. 1 and FIG. 3. The capping layer 128 has a top surface being coplanar with the top surface of the substrate 100, so that, each of the word lines 120 will therefore serve as a buried word line (BWL), being isolated from each bit line 150 through the insulating layer 110 disposed over the substrate 100.

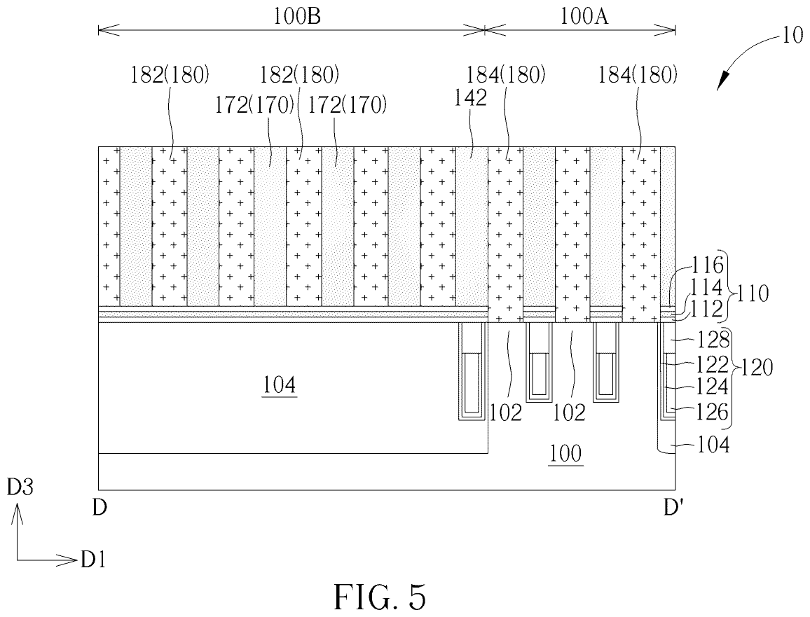

As shown in FIG. 1 and FIG. 5, the semiconductor device 10 further includes a plurality of plugs 180, each between the adjacent ones of the bit lines 150 in the second direction D2. The plugs 180 are electrically isolated from each other in the first direction D1 by arranging the insulating structures 170 therebetween in the first direction D1. It is noted that, in order to clearly illustrate the arrangement of specific components (for example the word lines 120, the bit lines 150 and the dummy bit lines 152), some elements such as the plugs 180 are omitted in FIG. 1 of the present embodiment, and those who skilled in the art should fully realize the location of the omitted components in FIG. 1 through the cross-sectional views as shown in FIG. 5. Precisely speaking, the plugs 180 further include a plurality of first plugs 182 and a plurality of second plugs 184, respectively within the peripheral region 100B and the cell region 100A. Each of the first plugs 182 is disposed on the insulating layer 110 over the substrate 100, without contacting any active area 102, and each of the second plugs 184 partially extends into the substrate 100 through the bottom thereof, to electrically connect to the active areas 102. In one embodiment, a storage node pad (SN pad, not shown in the drawings) is additionally disposed on each second plug 184. Accordingly, the second plugs 184 are configured as storage node contacts (SNCs) of the semiconductor device 10, electrically connecting to storage nodes formed subsequently, and the first plugs 182 are configured as dummy contacts of the semiconductor device 10, to balancing the difference of the elemental density between the cell region 100A and the peripheral region 100B, to improve the fabrication yield. In one embodiment, the first plugs 182 and the second plugs 184 for example includes a semiconductor material like polysilicon, or doped amorphous silicon, or a low-resistance metal material like aluminum, titanium, copper or tungsten, and preferably include the same semiconductor material as that of the semiconductor layer 132 of each bit line 150 or each dummy bit line 152, but not limited thereto.

According to the semiconductor device 10 of the present embodiment, the isolating structures 172 vertically penetrating the second bit line 140 and the fourth bit line 156, and the isolating structures 174 vertically penetrating the first bit line 130 and the third bit line 154, are arranged within the cell region 100A and within the peripheral region 100B respectively, so as to achieve various isolations in different regions. Thus, the arrangement of the isolating structures 170 is sufficient to improve the structural reliability, as well as the device performance, of the semiconductor device 10. With this arrangement, the semiconductor device 10 may be served as a dynamic random access memory (DRAM, not shown in the drawings), with at least one capacitor (not shown in the drawings) disposed over the second plugs 184 and at least one transistor (not shown in the drawings) disposed within the substrate 100 together forming the smallest memory cell of the DRAM array, for receiving the voltage signals from the bit lines 150 and the word lines 120.

In order to make those having ordinary skills in the art easily understand the semiconductor device 10 according to the present disclosure, a method of fabricating the semiconductor device 10 according to the present disclosure will be further described as follows.

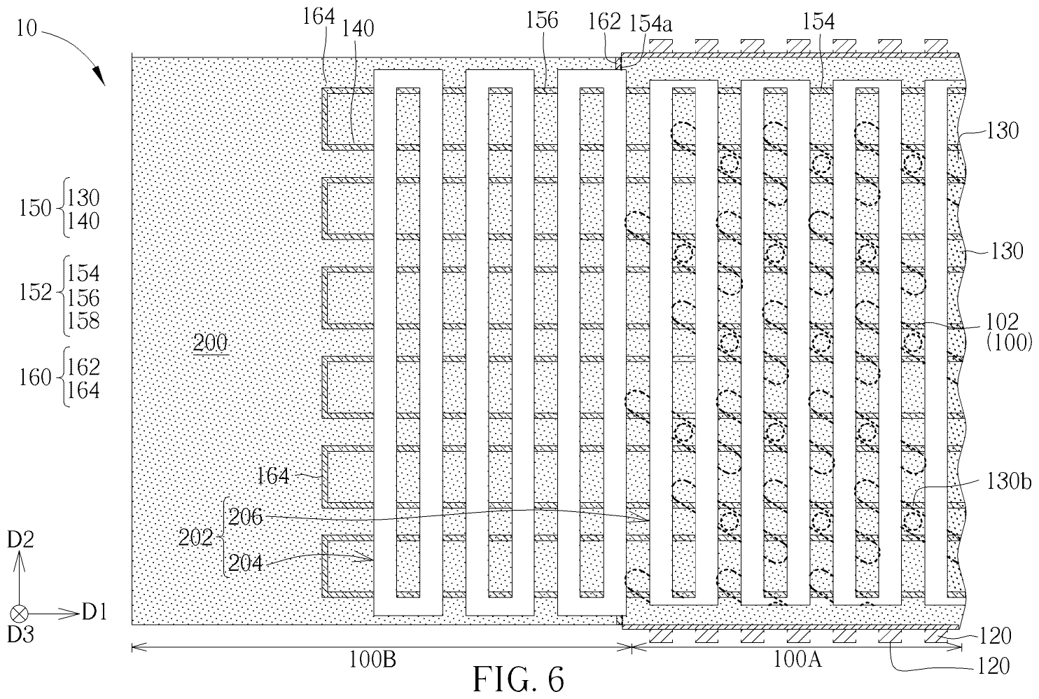

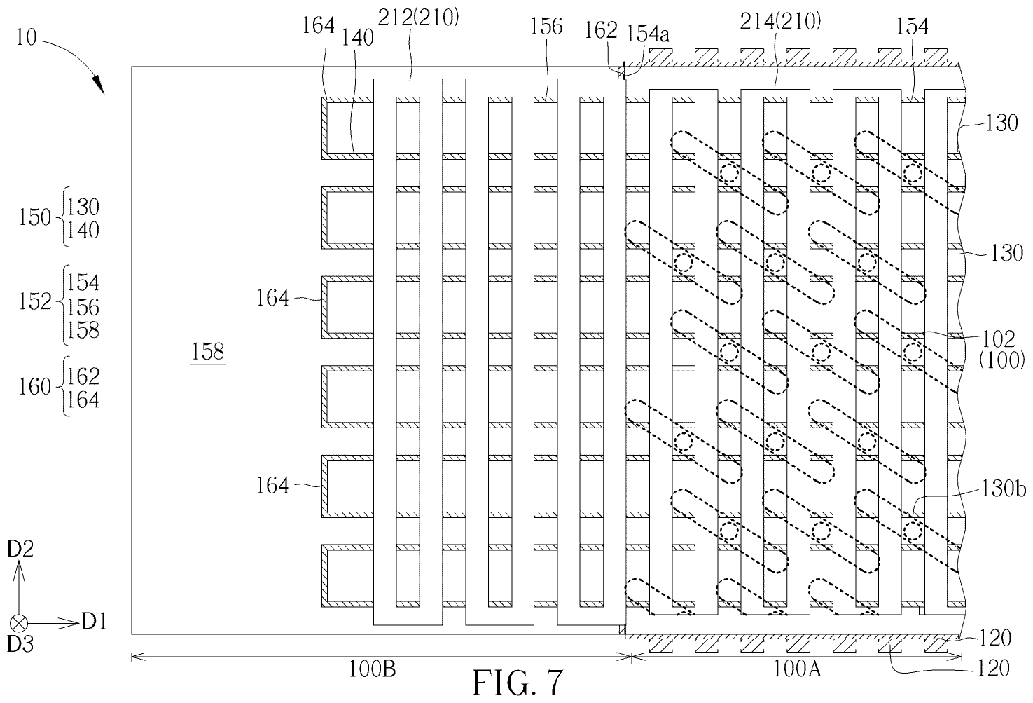

Please refer FIG. 6 to FIG. 7, which are schematic diagrams illustrating a method of fabricating a semiconductor device 10 according to the first embodiment of the present disclosure, with FIG. 6 and FIG. 7 respectively illustrating a top view of the semiconductor device 10 during the fabricating process. Although the cross-sectional views of the semiconductor device 10 taken in various cross lines during the fabricating process are not shown in the present embodiment, those who skilled in the art should fully realize the cross-sectional view of the semiconductor device 10 in each step as reference to the drawings above.

Firstly, as shown in FIG. 6, the substrate 100 is provided, and the shallow trench isolation 104 is formed in the substrate 100 to define a plurality of the active areas 102. In one embodiment, the fabrication of the shallow trench isolation 104 is carried out by firstly forming a plurality of shallow trenches (not shown in the drawings) in the substrate 100 through performing an etching process, and at least one insulating material (such as including silicon oxide) is filled in the shallow trenches, to form the shallow trench isolation 104 having a top surface being coplanar with the top surface of the substrate 100, but not limited thereto. Next, a plurality of the word lines 120 is formed in the second direction D2, within the substrate 100. In one embodiment, the fabricating process of the word lines 120 includes but not limited to the following steps. Firstly, a plurality trenches (not shown in the drawings) is formed across plural active areas 102 and the shallow trench isolation 104, and a dielectric layer 122 covering an entire surface of each trench, a gate dielectric layer 124 covering the lower surface of each trench, a gate electrode 126 filled in the bottom portion of each trench, and a capping layer 128 filled in the upper portion of each trench are formed in sequence.

Then, the insulating layer 110, a plurality of the bit lines 150, and a plurality of the dummy bit lines 152 are formed on the substrate 100, with each bit line 150 extending in the first direction D1, and including the first bit line 130 and the second bit line 140 respectively within the cell region 100A and the peripheral region 100B, and with each dummy bit line 152 also extending in the first direction D1, and including the third bit line 154 and the fourth bit line 156 respectively within the cell region 100A and the peripheral region 100B. The first bit line 130 of each bit line 150 is electrically connected to the active areas 102 through a corresponding bit line contact 130b formed underneath. In one embodiment, the formation of the bit lines 150 and the dummy bit lines 152 include but not limited to the following steps. Firstly, a plurality of openings (not shown in the drawings) is formed through a mask (not shown in the drawings), with the openings penetrating through the insulating layer 110 to expose the top surface of the substrate 100, and a semiconductor material layer (not shown in the drawings, for example including a semiconductor material like doped polysilicon or doped amorphous silicon) is formed on the substrate 100 to fill in the openings. Following these, a barrier material layer (not shown in the drawings, for example including a barrier material like titanium and/or titanium nitride, tantalum and/or tantalum nitride), a metal material layer (not shown in the drawings, for example including a low-resistant metal material like tungsten, aluminum, copper), and a capping material layer (not shown in the drawings, for example including an insulating material like silicon oxide, silicon nitride or silicon oxynitride) are formed in sequence on the semiconductor material layer, and a patterning process is performed on the capping material layer, the metal material layer, the barrier material layer and the semiconductor material layer, to simultaneously form the first bit line 130 of each bit line 150 and the third bit line 154 of each dummy bit line 152. Then, after removing the mask layer, an isolating material layer (not shown in the drawings, for example including a material like silicon oxide or silicon oxynitride) is formed on the substrate 100, and another patterning process is performed through another mask layer, to simultaneously form the second bit line 140 of each bit line 150 and the fourth bit line 156 of each dummy bit line 152, thereby forming the bit lines 150 and the dummy bit lines 152. The formations of the spacer 162 and the bit line spacer 164 are respectively performed before and after patterning the bit lines and the dummy bit lines 165. For example, before performing the patterning process, the spacer 162 is formed on the sidewalls of the aforementioned stacked layers, to define the short-end 130a of the first bit line. Then, after forming the bit lines 150 and the dummy bit lines 152, the bit line spacer 164 is formed on the sidewalls of the bit lines 150 and the dummy bit lines 152, but not limited thereto.

Further in view of FIG. 6, a sacrificial layer 200 and a plurality of mask patterns 202 are formed on the substrate 100, to respectively define the locations of the isolating structures 170 formed subsequently. The mask patterns 202 preferably each includes a circular shape as shown in FIG. 6, but not limited thereto. The mask patterns 202 further include a plurality of first mask patterns 204 within the peripheral region 100B, to intersect the second bit line 140 of each bit line 150 and the fourth bit line 156 of each dummy bit line 152 underneath, and a plurality of second mask patterns 206 within the cell region 100A, to intersect the first bit line 130 of each bit line 150 and the third bit line 154 of each dummy bit line 152 underneath. The first mask patterns 204 within the peripheral region 100B preferably include an extending length in the second direction D2, being larger than that of the second mask patterns 206 in the second direction D2, but not limited thereto. In one embodiment, the formation of the mask patterns 202 is but is not limited to be carried out through a self-aligned double patterning process (SADP), or a self-aligned reverse patterning process (SARP). Those who skilled in the arts should fully realize that, in another embodiment, the first mask patterns 204 within the peripheral region 100B and the second mask patterns 206 within the cell region 100A may optionally include the same extending length in the second direction D2.

Please refer to FIG. 7, an etching process is performed through the mask patterns 202, to partially remove the sacrificial layer 200 and the corresponding portions of the bit lines 150 and the dummy bit lines 152 underneath, to form a plurality of trenches 210. Then, the mask patterns 202 are completely removed. The trenches 210 for example each includes the circular shape as shown in FIG. 7, but not limited thereto. Precisely speaking, the trenches 210 further includes a plurality of first trenches 212 within the peripheral region 100B, to partially expose the second bit line 140 of each bit line 150 and the fourth bit line 156 of each dummy bit line 152 underneath, and a plurality of second trenches 214 within the cell region 100A, to partially expose the first bit line 130 of each bit line 150 and the third bit line 154 of each dummy bit line 152 underneath.

Afterward, a deposition process and an etching back process are performed on the substrate 100, to fill an isolating material in the trenches 210, thereby forming the isolating structures 170 as shown in FIG. 1 to FIG. 5. Then, at least one etching process and a deposition process may be performed on the substrate 100, to form a conductive material layer (not shown in the drawings, including a low-resistance metal material like aluminum, titanium, copper or tungsten), followed by forming the plugs 180 as shown in FIG. 5. Thus, the fabrication of the semiconductor device 10 is completed.

According to the fabricating process of the semiconductor device 10, the isolation structures 172 and 174 having various extension lengths and penetrating components with various materials are respectively disposed within different regions (including the cell region 100A and the peripheral region 100B) of the substrate 100 at the same time, so as to achieve various isolation effects in the different regions. Then, it is sufficient to improve the structural reliability, as well as the device performance, of the semiconductor device 10. With these performances, a plurality of capacitors (not shown in the drawings) can be formed subsequently on the plugs 180, such that, the semiconductor device 10 of the present embodiment may therefore serve as the DRAM.

Those of ordinary skill in the art should easily realize the semiconductor device and the fabricating method thereof in the present disclosure are not limited to the aforementioned embodiment, and which may include other examples or varieties. The following description will detail the different embodiments of the semiconductor device and the fabricating method thereof in the present disclosure. To simplify the description, the following description will detail the dissimilarities among the different embodiments and the identical features will not be redundantly described. In order to compare the differences between the embodiments easily, the identical components in each of the following embodiments are marked with identical symbols.

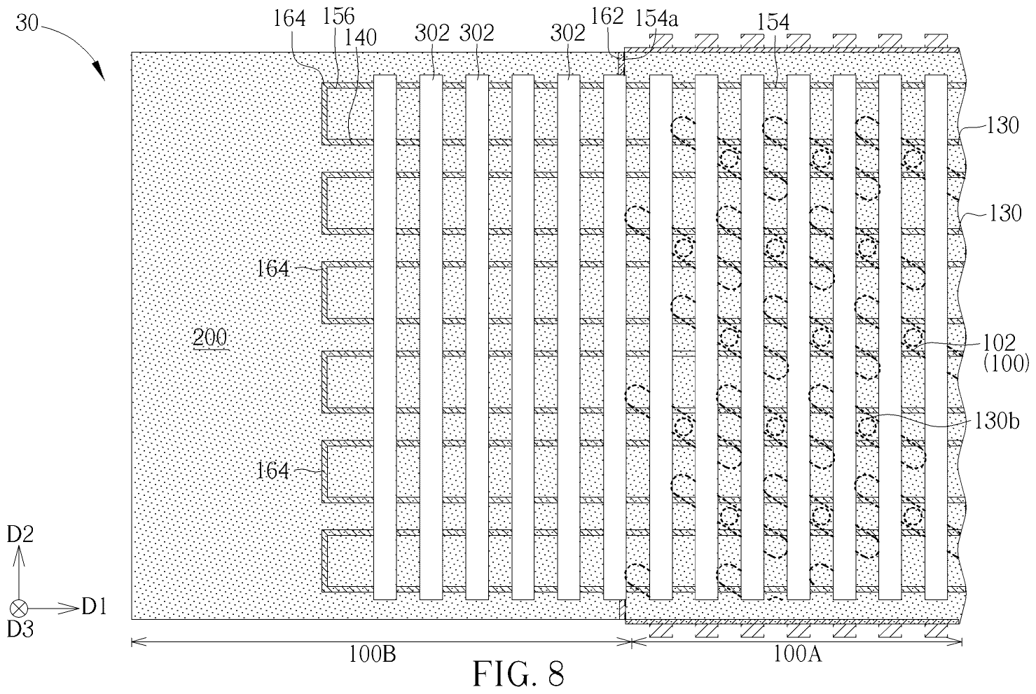

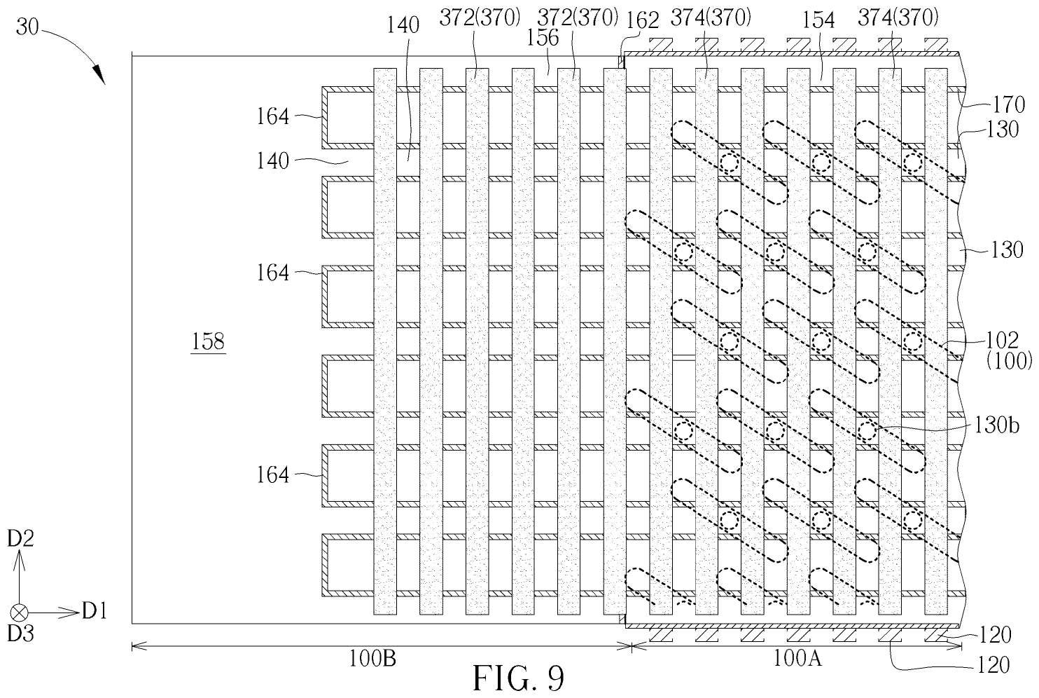

Please refer to FIG. 8 and FIG. 9, which are schematic diagrams illustrating a fabricating method of a semiconductor device 30 according to the second embodiment of the present disclosure, with FIG. 8 and FIG. 9 respectively illustrating a top view of the semiconductor device 30 during the fabricating process. The fabricating process of the semiconductor device 30 in the present embodiment is substantially the same as those of the semiconductor device 10 in the aforementioned embodiment, and all the similarities will not be redundantly described hereinafter. The difference between the semiconductor device 30 of the present embodiment and the aforementioned embodiment is mainly in that, at least one of isolating structures 370 is in a stripe shape.

Precisely speaking, as shown in FIG. 8, a plurality of mask patterns 302 is formed on the sacrificial layer 200, to respectively define the locations of the isolating structures 370 formed subsequently, with the mask patterns 302 preferably each having a stripe shape, but not limited thereto. In the present embodiment, the mask patterns 302 are formed within the peripheral region 100B and the cell region 100A respectively, and which have the same extending length in the second direction D2, but not limited thereto. It is noted that, the mask patterns 302 formed within the peripheral region 100B intersect the second bit line 140 of each bit line 150 and the fourth bit line 156 of each dummy bit line 152 underneath, and the mask patterns 302 formed within the cell region 100A intersect the first bit line 130 of each bit line 150 and the third bit line 154 of each dummy bit line 152 underneath.

As shown in FIG. 9, an etching process is performed through the mask patterns 302, to partially remove the sacrificial layer 200 and the corresponding portions of the bit lines 150 and the dummy bit lines 152 underneath, to form a plurality of trenches (not shown in the drawings), followed by filling an insulating material in the trenches, to form the isolating structures 370. Precisely speaking, the isolating structures 372 are formed within the peripheral region 100B, to intersect the second bit line 140 of each bit line 150 and to intersect a portion of the fourth bit line 156 of each dummy bit line 152 in the second direction D2. The isolating structures 374 are formed within the cell region 100A, to intersect the first bit line 130 of each bit line 150 and to intersect a portion of the third bit line 154 of each dummy bit line 152 in the second direction D2.

After that, at least one etching process and a deposition process are performed on the substrate 100, to form the plugs as shown in FIG. 5 of the aforementioned embodiment, thereby completing the fabrication of the semiconductor device 30 of the present embodiment. According to the fabricating process of the semiconductor device 30, the isolation structures 372 and 374 penetrating components with various materials are respectively formed within different regions (including the cell region 100A and the peripheral region 100B) of the substrate 100 at the same time, so as to achieve various isolation effects in the different regions. Then, it is sufficient to improve the structural reliability, as well as the device performance, of the semiconductor device 30. With these performances, a plurality of capacitors (not shown in the drawings) can be formed subsequently on the plugs, such that, the semiconductor device 30 of the present embodiment may serve as the DRAM.

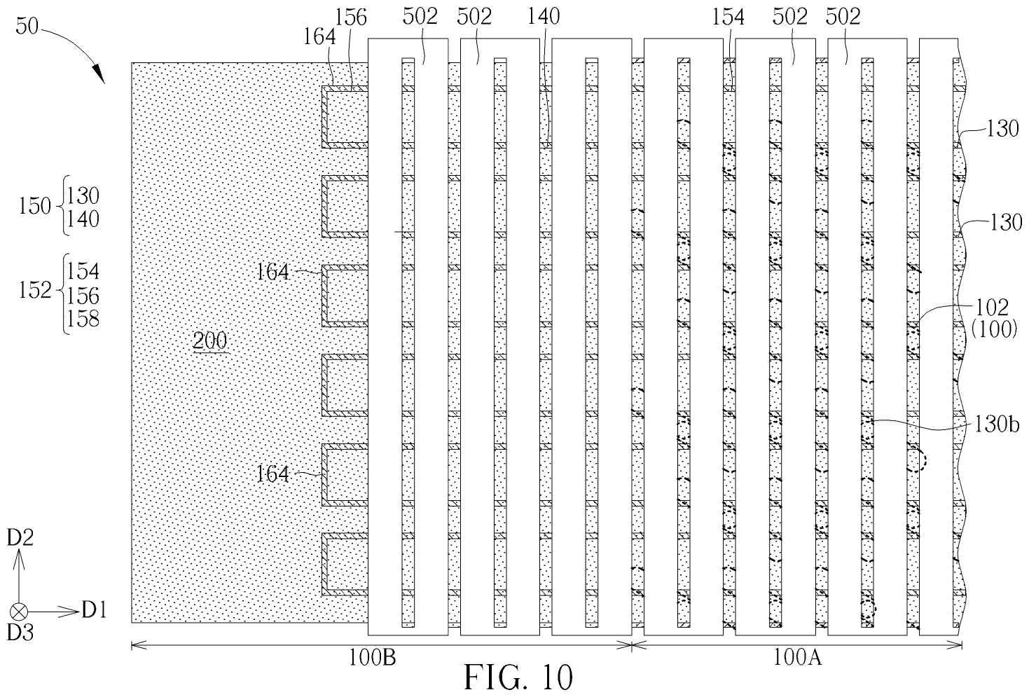

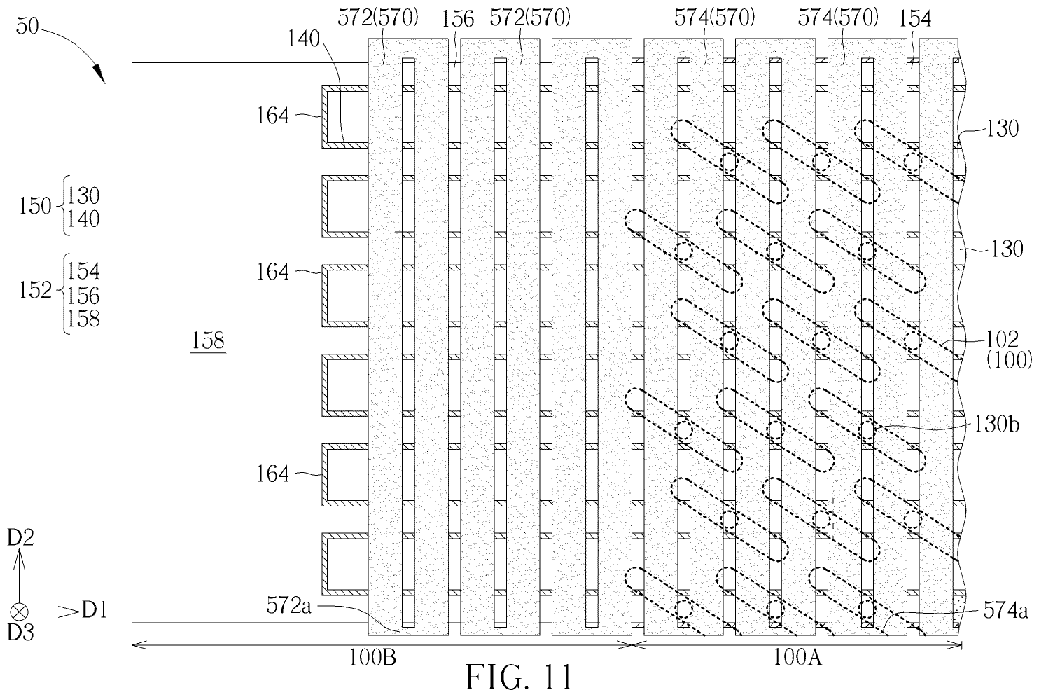

Please refer to FIG. 10 and FIG. 11, which are schematic diagrams illustrating a fabricating method of a semiconductor device 50 according to the third embodiment of the present disclosure, with FIG. 10 and FIG. 11 respectively illustrating a top view of the semiconductor device 50 during the fabricating process. The fabricating process of the semiconductor device 50 in the present embodiment is substantially the same as those of the semiconductor device 10 in the aforementioned embodiment, and all the similarities will not be redundantly described hereinafter. The difference between the semiconductor device 50 of the present embodiment and the aforementioned embodiment is mainly in that, short-ends 572a, 574a of at least one of isolating structures 570 is disposed at a side of the dummy bit line 152 in the first direction D1, with the side being away from the bit lines 150.

Precisely, as shown in FIG. 10, a plurality of mask patterns 502 is formed on the sacrificial layer 200, to respectively define the locations of the isolating structures 570 formed subsequently, with the mask patterns 502 preferably each having a circular shape, but not limited thereto. In the present embodiment, the mask patterns 502 are formed within the peripheral region 100B and the cell region 100A, respectively, and which preferably have the same extending length in the second direction D2, but not limited thereto. It is noted that, the mask patterns 502 formed within the peripheral region 100B intersect the second bit line 140 of each bit line 150 and the fourth bit line 156 of each dummy bit line 152 underneath, and the mask patterns 502 formed within the cell region 100A intersect the first bit line 130 of each bit line 150 and the third bit line 154 of each dummy bit line 152 underneath.

As shown in FIG. 11, an etching process is performed through the mask patterns 502, to partially remove the sacrificial layer 200 and the corresponding portions of the bit lines 150 and the dummy bit lines 152 underneath, to form a plurality of trenches (not shown in the drawings), followed by filling an insulating material in the trenches, to form the isolating structures 570. Precisely speaking, the isolating structures 572 are formed within the peripheral region 100B, to intersect the second bit line 140 of each bit line 150 and the fourth bit line 156 of each dummy bit line 152 in the second direction D2. The isolating structures 574 are formed within the cell region 100A, to intersect the first bit line 130 of each bit line 150 and the third bit line 154 of each dummy bit line 152 in the second direction D2. In this way, the short-ends 572a, 574a of the isolating structures 570 in the first direction D1 are disposed at the side of the dummy bit line 152, being away from the bit lines 150.

After that, at least one etching process and a deposition process are performed on the substrate 100, to form the plugs as shown in FIG. 5 of the aforementioned embodiment, thereby completing the fabrication of the semiconductor device 50 of the present embodiment. According to the fabricating process of the semiconductor device 50, the isolation structures 572 and 574 penetrating components with various materials are respectively formed within different regions (including the cell region 100A and the peripheral region 100B) of the substrate 100 at the same time, so as to achieve various isolation effects in the different regions. Then, it is sufficient to improve the structural reliability, as well as the device performance, of the semiconductor device 50. With these performances, a plurality of capacitors (not shown in the drawings) can be formed subsequently on the plugs, such that, the semiconductor device 50 of the present embodiment may serve as the DRAM.

In overall speaking, according to the semiconductor device and the fabricating method thereof, the isolating structures having various extension lengths and/or penetrating components with various materials are respectively disposed within different regions (including the cell region 100A and the peripheral region 100B) of the substrate 100 at the same time, so as to achieve various isolation effects in the different regions, and to improve the structural reliability, as well as the device performance, of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a plurality of bit lines, disposed on the substrate, the bit lines extending in a first direction and being arranged in a second direction perpendicular to the first direction, wherein at least one of the bit lines comprises a first bit line and a second bit line, and the second bit line is disposed adjacent to a short-end of the first bit line extending in the second direction;
a spacer, disposed between the first bit line and the second bit line, and in physical contact with the first bit line and the second bit line; and
an isolating structure, disposed on the substrate and simultaneously covering a portion of the first bit line, a portion of the second bit line and a portion of the spacer.

2. The semiconductor device according to claim 1, wherein the isolating structure penetrates through the second bit line in a third direction being perpendicular to the first direction and the second direction.

3. The semiconductor device according to claim 1, wherein the second bit line comprises an insulating layer disposed on the substrate in the third direction, the first bit line comprises a semiconductor layer, a barrier layer, a conductive layer, and a capping layer stacked in sequence on the substrate in the third direction, and the isolating structure physically contacts a top surface of the conductive layer of the first bit line.

4. The semiconductor device according to claim 1, wherein the isolating structure physically contacts sidewalls of the first bit line and the second bit line, and a sidewall and a top surface of the spacer.

5. The semiconductor device according to claim 1, wherein an upper width of the isolating structure is larger than a bottom width of the isolating structure.

6. The semiconductor device according to claim 2, further comprising:
a dummy bit line extending in the first direction and disposed at one side of all of the bit lines, a width of the dummy bit line in the second direction is larger than 1.3 times of an average width of the bit lines, wherein the dummy bit line comprises a third bit line at a side of the first bit line, and a fourth bit line at a side of the second bit line, and the fourth bit lines is disposed adjacent to a short-end of the third bit line extending in the second direction.

7. The semiconductor device according to claim 6, wherein the isolating structure penetrates through the fourth bit line of the dummy bit line in the third direction.

8. The semiconductor device according to claim 6, wherein the fourth bit line of the dummy bit line and the second bit line of the at least one bit line are connected with each other in the second direction.

9. The semiconductor device according to claim 6, wherein the third bit line further includes a semiconductor layer, a barrier layer, a conductive layer, and a capping layer stacked in sequence on the substrate in the third direction, and the isolating structure physically contacts a top surface of the conductive layer of the third bit line.

10. The semiconductor device according to claim 6, wherein the isolating structure comprises a stripe shape or a circular shape.

11. The semiconductor device according to claim 10, wherein a short-end of the isolating structure extending in the first direction is disposed within the dummy bit line.

12. The semiconductor device according to claim 10, wherein a short-end of the isolating structure in the second direction is disposed at one side of the dummy bit line being away from the bit lines.

13. The semiconductor device according to claim 10, wherein the isolating structure intersects the second bit line of the at least one bit line, and intersect a portion of the fourth bit line of the dummy bit line in the second direction.

14. A method of fabricating a semiconductor device, comprising:
providing a substrate;
forming a plurality of bit lines on the substrate, the bit lines extending in a first direction and being arranged in a second direction perpendicular to the first direction, wherein at least one of the bit lines comprises a first bit line and a second bit line, and the second bit line is disposed adjacent to a short-end of the first bit line extending in the second direction;
forming a spacer between the first bit line and the second bit line, physical contacting the first bit line and the second bit line respectively; and
forming an isolating structure on the substrate, simultaneously covering a portion of the first bit line, a portion of the second bit line and a portion of the spacer.

15. The method of fabricating a semiconductor device according to claim 14, wherein the isolating structure penetrates through the second bit line in a third direction being perpendicular to the first direction and the second direction.

16. The method of fabricating a semiconductor device according to claim 14, forming the isolating structure comprising:
forming a sacrificial layer on the substrate;
performing a self-aligned reverse patterning process on the sacrificial layer, to form a mask pattern, wherein the mask pattern partially overlaps the second bit line of the at least one bit line in the third direction;
etching the sacrificial layer through the mask pattern, to form a trench intersecting each of the bit lines in the second direction; and
filling an insulating material in the trench, to form the isolating structure.

17. The method of fabricating a semiconductor device according to claim 16, further comprising:
forming a dummy bit line on the substrate, extending in the first direction and disposed at one side of all of the bit lines, a width of the dummy bit line in the second direction is larger than 1.3 times of an average width of the bit lines, wherein the dummy bit line comprises a third bit line at a side of the first bit line, and a fourth bit line at a side of the second bit line, and the fourth bit lines is adjacent to a short-end of the third bit line extending in the second direction.

18. The method of fabricating a semiconductor device according to claim 17, wherein the fourth bit line of the dummy bit line and the second bit line of the at least one bit line are connected in the second direction, and the trench intersects a portion of the fourth bit line of the dummy bit line in the second direction.

19. The method of fabricating a semiconductor device according to claim 17, wherein the fourth bit line of the dummy bit line and the second bit line of the at least one bit line are connected in the second direction, and the trench intersects the fourth bit line of the dummy bit line in the second direction.

20. The method of fabricating a semiconductor device according to claim 16, wherein the mask pattern comprises a stripe shape or a circular shape.
